(19) United States
(12) Patent Application Publication
(10) Pub. No.: US 2025/0311506 A1
(43) Pub. Date: Oct. 2, 2025

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., LTD., Yongin-si (KR)

(72) Inventors: Hyeongsu Choi, Yongin-si (KR); INHYUK KIM, Yongin-si (KR); SANGHYUNG LIM, Yongin-si (KR); SANGWOOK HAN, Yongin-si (KR)

(21) Appl. No.: 19/011,417

(22) Filed: Jan. 6, 2025

(30) Foreign Application Priority Data
Apr. 1, 2024 (KR) 10-2024-0044284

(51) Int. Cl. H10H 29/80; H01L 25/075; H10H 29/01

(52) U.S. Cl. CPC H10H 29/8325; H01L 25/0753; H10H 29/032; H10H 29/942

(57) ABSTRACT

A display device a substrate, a driving element above the substrate, a lower electrode above the driving element, a barrier layer entirely covering a side surface of the lower electrode, and including a polymer, and a light-emitting element above the lower electrode.

### CROSS-REFERENCE TO RELATED APPLICATION

The present application claims priority to, and the benefit of, Korean Patent Application No. 10-2024-0044284, filed on Apr. 1, 2024, in the Korean Intellectual Property Office, the disclosure of which is herein incorporated by reference in its entirety.

### BACKGROUND

### 1. Field

The present disclosure relates to a display device, a method of manufacturing the display device, and an electronic device including the display device.

### 2. Description of the Related Art

A light-emitting diode (“LED”) is a device that converts an electric signal into a form of light, such as infrared light, visible light, etc. by utilizing the characteristics of a compound semiconductor. For example, the light-emitting diode is a semiconductor device that, when a voltage is applied to a P—N diode in a forward direction, holes and electrons are injected, and the energy generated by the recombination of the holes and the electrons is converted into light energy.

### SUMMARY

Embodiments provide a display device including a light-emitting element with improved reliability.

Embodiments provide a method of manufacturing the display device.

Embodiments provide an electronic device including the display device.

A display device according to one or more embodiments of the present disclosure includes a substrate, a driving element above the substrate, a lower electrode above the driving element, a barrier layer entirely covering a side surface of the lower electrode, and including a polymer, and a light-emitting element above the lower electrode.

The barrier layer may include a fluorine-based polymer.

The display device may further include a reflective electrode between the driving element and the lower electrode, and having a side surface entirely covered by the barrier layer.

The reflective electrode may include aluminum or silver.

The display device may further include an adhesive layer between the driving element and the reflective electrode, including an alloy, and having a side surface entirely covered by the barrier layer.

The light-emitting element may include a first semiconductor layer above the lower electrode, an active layer above the first semiconductor layer, and a second semiconductor layer above the active layer.

The display device may further include an upper electrode above the light-emitting element, and an element protection layer that entirely covers a side surface of the light-emitting element and a side surface of the upper electrode.

A method of manufacturing a display device according to one or more embodiments of the present disclosure includes forming a driving element above a first substrate, forming a first preliminary electrode layer above the driving element, forming a preliminary element layer above the first preliminary electrode layer, forming a second preliminary electrode layer above the preliminary element layer, forming a light-emitting element, and an upper electrode above the light-emitting element, by patterning the preliminary element layer and the second preliminary electrode layer, respectively, and concurrently forming a lower electrode, and a barrier layer that entirely covers a side surface of the lower electrode, under the light-emitting element by patterning the first preliminary electrode layer.

The barrier layer may include a fluorine-based polymer.

The patterning the first preliminary electrode layer may include forming a photoresist pattern above the first preliminary electrode layer, and using the photoresist pattern as a first etching mask through a first etching process.

The patterning the first preliminary electrode layer may include using an etching gas including a fluorine-based gas in a dry etching process.

The fluorine-based gas may include at least one of CF₄, C₃F₆, C₄F₈, CHF₃, CH₂F₂, or C₂HF₅.

The method may further include forming an adhesive layer above the driving element, and forming a reflective electrode layer above the adhesive layer and below the first preliminary electrode layer.

The method may further include forming a reflective electrode by patterning the reflective electrode layer concurrently with the first preliminary electrode layer through the first etching process, wherein the barrier layer entirely covers a side surface of the reflective electrode.

The method may further include patterning the adhesive layer using the photoresist pattern and the barrier layer as a second etching mask through a second etching process after the patterning the first preliminary electrode layer.

The adhesive layer and the reflective electrode layer may be patterned concurrently with the first preliminary electrode layer through the first etching process, wherein the barrier layer is formed to entirely cover a side surface of the patterned adhesive layer and a side surface of the patterned reflective electrode layer.

The method may further include removing the photoresist pattern after the forming the barrier layer, and forming an element protection layer that entirely covers a side surface of the light-emitting element and a side surface of the upper electrode.

The method may further include forming an element protection layer that entirely covers a side surface of the light-emitting element and a side surface of the upper electrode before the forming the barrier layer.

The preliminary element layer and the second preliminary electrode layer may be patterned concurrently.

The forming the first preliminary electrode layer above the driving element may include forming the first preliminary electrode layer above a second substrate, bonding the first substrate and the second substrate so that the first preliminary electrode layer is above the driving element, and removing the second substrate.

An electronic device according to one or more embodiments of the present disclosure includes a display device including a light-emitting element and a power supply configured to provide power to the display device. The display device includes a substrate, a driving element above the substrate, a lower electrode above the driving element, a barrier layer entirely covering a side surface of the lower electrode, and including a polymer, and the light-emitting element above the lower electrode.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a cross-sectional view taken along the line I-I′ of FIG. 1.

FIG. 3 is a cross-sectional view illustrating a display device according to one or more other embodiments of the present disclosure.

FIGS. 4, 5, 6, 7, 8, 9, 10, 11, 12, and 13 are cross-sectional views illustrating a method of manufacturing a display device according to one or more embodiments of the present disclosure.

FIGS. 14, 15, 16, 17, and 18 are cross-sectional views illustrating a method of manufacturing a display device according to one or more other embodiments of the present disclosure.

FIG. 19 is a block diagram illustrating an electronic device according to an embodiment of the present disclosure.

FIG. 20 is a view illustrating an example in which the electronic device of FIG. 19 is implemented as a head mounted display device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be substantially perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

A display device according to one or more embodiments of the present disclosure may include a barrier layer that entirely covers a side surface of a lower electrode, and that includes a polymer, and a light-emitting element located on the lower electrode.

The barrier layer may protect the side surface of the lower electrode during a manufacturing process of the display device. For example, the barrier layer may protect the lower electrode from a chlorine anion and a chlorine radical generated in an etching process. Accordingly, corrosion of the lower electrode may be reduced or prevented, and reliability of the light-emitting element may be improved.

A method of manufacturing a display device according to one or more embodiments of the present disclosure may include forming the lower electrode and the barrier layer that entirely covers the side surface of the lower electrode concurrently or substantially simultaneously by patterning a first preliminary electrode layer. For example, when etching the first preliminary electrode layer by supplying an etching gas including a fluorine-based gas, and by adjusting a process condition, the lower electrode and the barrier layer may be formed concurrently or substantially simultaneously. In other words, the barrier layer may be formed concurrently or substantially simultaneously in a process of forming the lower electrode without an additional process for forming the barrier layer.

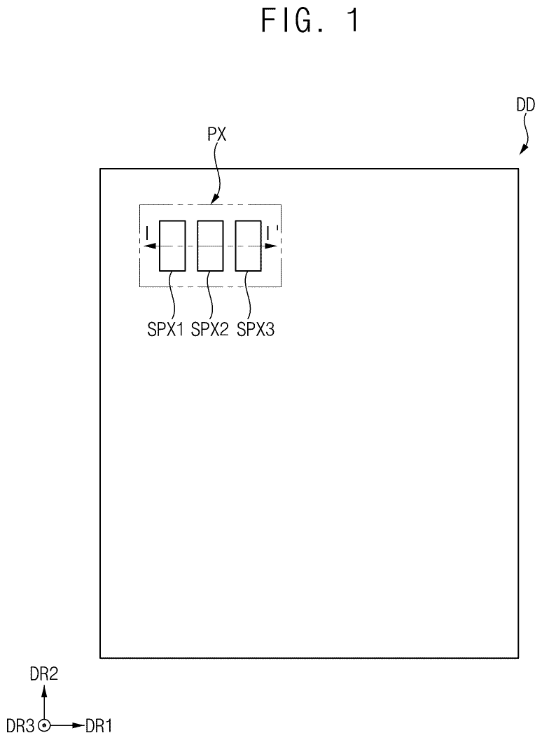

FIG. 1 is a plan view illustrating a display device according to one or more embodiments of the present disclosure.

In this specification, a plane may be defined by a first direction DR1 and by a second direction DR2 intersecting the first direction DR1. For example, the first direction DR1 and the second direction DR2 may be substantially perpendicular to each other. A direction normal to the plane, that is, a thickness direction of a display device DD may be a third direction DR3. In other words, the third direction DR3 may be substantially perpendicular to each of the first direction DR1 and the second direction DR2.

Referring to FIG. 1, the display device DD according to one or more embodiments of the present disclosure may include a plurality of pixels PX. The pixels PX may be arranged repeatedly along the first direction DR1 and the second direction DR2. Each of the pixels PX may include a first sub-pixel SPX1, a second sub-pixel SPX2, and a third sub-pixel SPX3.

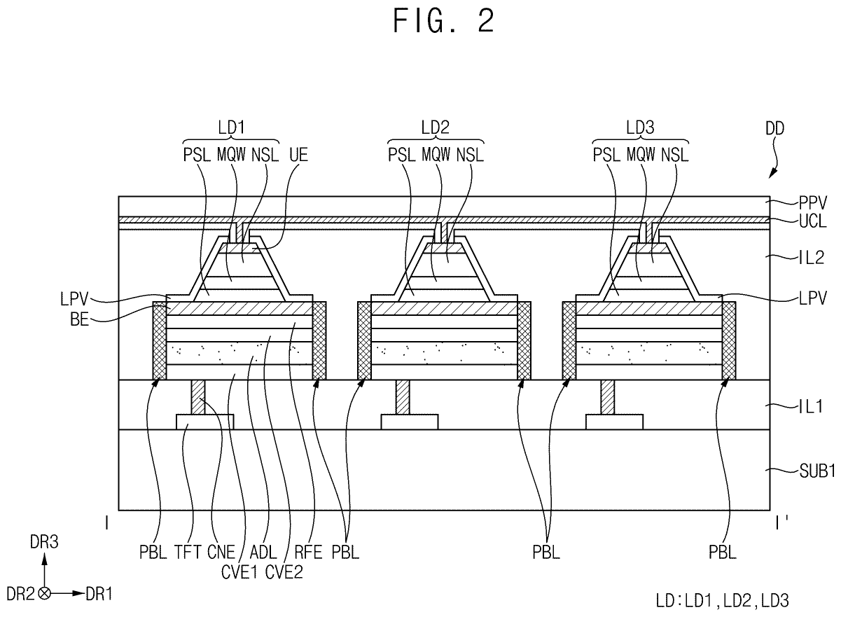

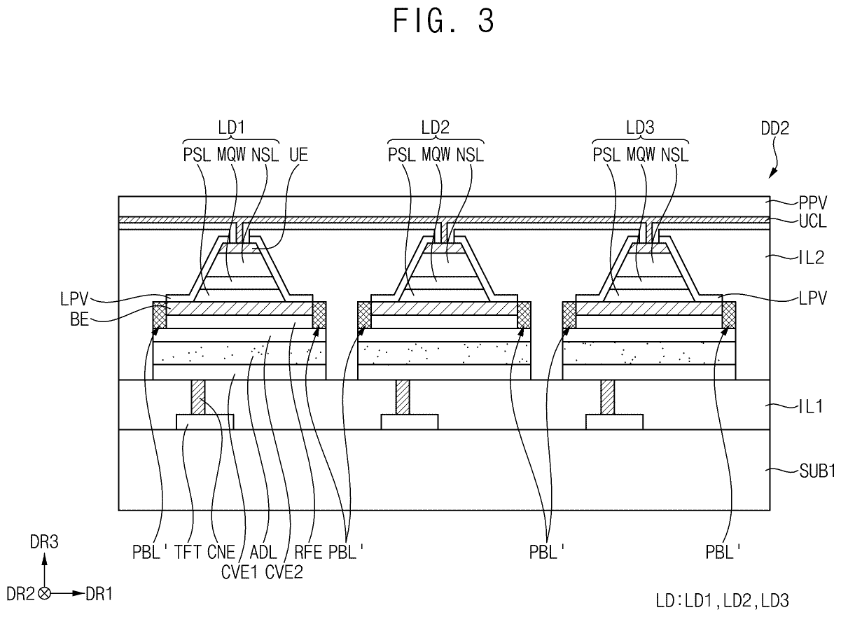

The first sub-pixel SPX1 may emit light of a first color, the second sub-pixel SPX2 may emit light of a second color, and the third sub-pixel SPX3 may emit light of a third color. The first sub-pixel SPX1 may include a first light-emitting element (LD1, see FIG. 2) that generates light of the first color. The second sub-pixel SPX2 may include a second light-emitting element (LD2, see FIG. 2) that generates light of the second color. The third sub-pixel SPX3 may include a third light-emitting element (LD3, see FIG. 3) that generates light of the third color. For example, the first color may be red, the second color may be green, and the third color may be blue, but the present disclosure is not limited thereto. An image may be displayed by a combination of lights emitted by the first sub-pixel SPX1, the second sub-pixel SPX2, and the third sub-pixel SPX3.

In one or more embodiments, the display device DD may be a micro-LED display device. In this case, each of the first light-emitting element, the second light-emitting element, and the third light-emitting element may be a micro light-emitting diode. However, the present disclosure is not limited thereto. For example, the display device DD may be any one of an organic light-emitting diode display device, a liquid crystal display device, an organic light-emitting diode on silicon (“OLEDOS”), an inorganic light-emitting diode (“ILED”) display device, and a quantum dot emitting display device.

FIG. 2 is a cross-sectional view taken along the line I-I′ of FIG. 1.

Referring to FIG. 2, the display device DD according to one or more embodiments of the present disclosure may include a first substrate SUB1, a driving element TFT, a connection electrode CNE, a first insulating layer IL1, a first cover electrode CVE1, an adhesive layer ADL, a second cover electrode CVE2, a reflective electrode RFE, a lower electrode BE, a barrier layer PBL, a light-emitting element LD, an upper electrode UE, an element protection layer LPV, a second insulating layer IL2, an upper electrode connection line UCL, and an upper protection layer PPV.

The light-emitting element LD may include a first light-emitting element LD1, a second light-emitting element LD2, and a third light-emitting element LD3. Each of the first light-emitting element LD1, the second light-emitting element LD2, and the third light-emitting element LD3 may include a first semiconductor layer PSL, an active layer MQW, and a second semiconductor layer NSL.

The first substrate SUB1 may include a transparent material or an opaque material. The first substrate SUB1 may be formed of a transparent resin substrate. A polyimide substrate may be an example of the transparent resin substrate. In this case, the polyimide substrate may include a first organic layer, a first barrier layer, a second organic layer, etc. Alternatively, the first substrate SUB1 may include a quartz substrate, a synthetic quartz substrate, a calcium fluoride substrate, a fluorine-doped quartz substrate, a soda-lime glass substrate, a non-alkali glass substrate, etc. These may be used alone or in combination with each other. In one or more embodiments, the first substrate SUB1 may be a silicon wafer.

The driving element TFT may be located on the first substrate SUB1. The driving element TFT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. They may be used alone or in combination with each other. The silicon semiconductor may include amorphous silicon, polycrystalline silicon, etc.

The first insulating layer IL1 may be located on the first substrate SUB1. The first insulating layer IL1 may cover the driving element TFT. The first insulating layer IL1 may include an inorganic insulating layer and/or an organic insulating layer. The inorganic insulating layer may include silicon oxide (SiOₓ), silicon nitride (SiNx), silicon oxynitride (SiOₓN_{y}), etc. These may be used alone or in combination with each other. The organic insulating layer may include a polyacryl-based resin, a polyimide-based resin, a polyamide-based resin, a siloxane-based resin, an acryl-based resin, an epoxy-based resin, etc. These may be used alone or in combination with each other. The first insulating layer IL1 may define a first opening exposing a portion of the driving element TFT. The first opening may penetrate the first insulating layer IL1 in a thickness direction (e.g., the third direction DR3).

The connection electrode CNE may be located on the driving element TFT. For example, the connection electrode CNE may be connected to the driving element TFT through the first opening penetrating the first insulating layer IL1. The connection electrode CNE may electrically connect the driving element TFT and the first cover electrode CVE1. The connection electrode CNE may include a metal, an alloy, a metal nitride, a conductive metal oxide, a transparent conductive material, etc. Examples of a material that may be used as the connection electrode CNE may include silver (Ag), an alloy including silver, molybdenum (Mo), an alloy including molybdenum, aluminum (AI), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in combination with each other.

The first cover electrode CVE1 may be located on the first insulating layer IL1. The first cover electrode CVE1 may cover the driving element TFT and the connection electrode CNE. The first cover electrode CVE1 may reduce or prevent penetration of impurities, moisture, etc. into the driving element TFT and the connection electrode CNE during a manufacturing process of the display device DD. The first cover electrode CVE1 may include a metal, an alloy, a metal nitride, a conductive metal oxide, a transparent conductive material, etc. In one or more embodiments, the first cover electrode CVE1 may include titanium (Ti), titanium nitride (TIN), etc. These may be used alone or in combination with each other. However, the present disclosure is not limited thereto.

The adhesive layer ADL may be located on the first cover electrode CVE1. The adhesive layer ADL may be located between the first cover electrode CVE1 and the second cover electrode CVE2. The adhesive layer ADL may attach the first cover electrode CVE1 and the second cover electrode CVE2. For example, the adhesive layer ADL may include gold (Au), tin (Sn), silver (Ag), aluminum (AI), titanium (Ti), etc. In one or more embodiments, the adhesive layer ADL may include a tin-gold (Sn—Au) alloy. However, the present disclosure is not limited thereto.

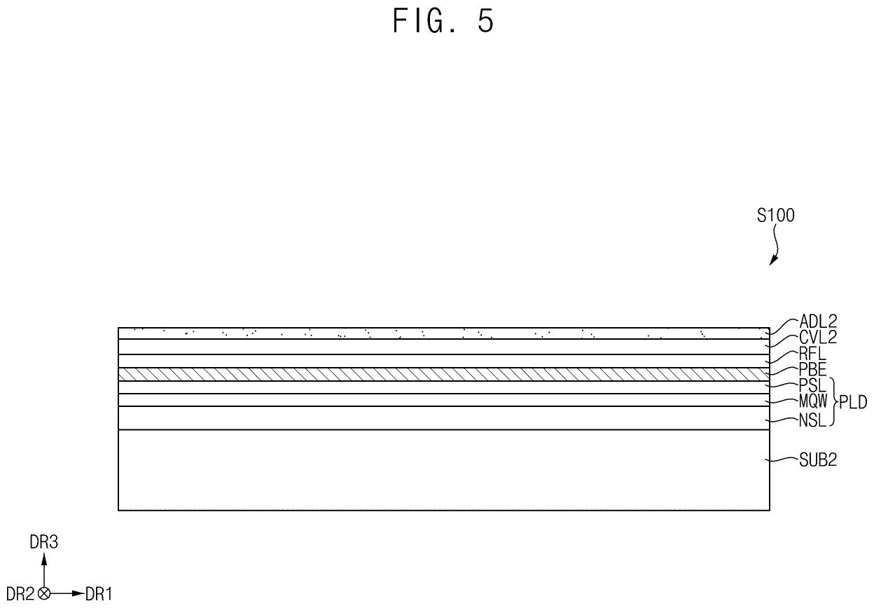

The second cover electrode CVE2 may be located on the adhesive layer ADL. The second cover electrode CVE2 may reduce or prevent penetration of impurities, moisture, etc. into a reflective electrode layer (RFL, see FIG. 5) and a first preliminary electrode layer (PBE, see FIG. 5) during the manufacturing process of the display device DD. The second cover electrode CVE2 may include a metal, an alloy, a metal nitride, a conductive metal oxide, a transparent conductive material, etc. In one or more embodiments, the second cover electrode CVE2 may include titanium (Ti), titanium nitride (TiN), etc. These may be used alone or in combination with each other. However, the present disclosure is not limited thereto.

The reflective electrode RFE may be located on the second cover electrode CVE2. The reflective electrode RFE may reflect light emitted from the active layer MQW. The reflective electrode RFE may include a metal having high light reflectivity. In one or more embodiments, the reflective electrode RFE may include aluminum (Al) or silver (Ag). However, the present disclosure is not limited thereto.

The lower electrode BE may be located on the reflective electrode RFE. The lower electrode BE may be electrically connected with the driving element TFT. In addition, the lower electrode BE may be electrically connected with the first semiconductor layer PSL. For example, the lower electrode BE may be referred to as a p-type electrode. The lower electrode BE may include a metal, an alloy, a metal nitride, a conductive metal oxide, a transparent conductive material, etc. In one or more embodiments, the lower electrode BE may include a transparent conductive oxide. In this case, the lower electrode BE may include indium tin oxide (“ITO”). However, the present disclosure is not limited thereto. For example, the lower electrode BE may serve as an anode electrode.

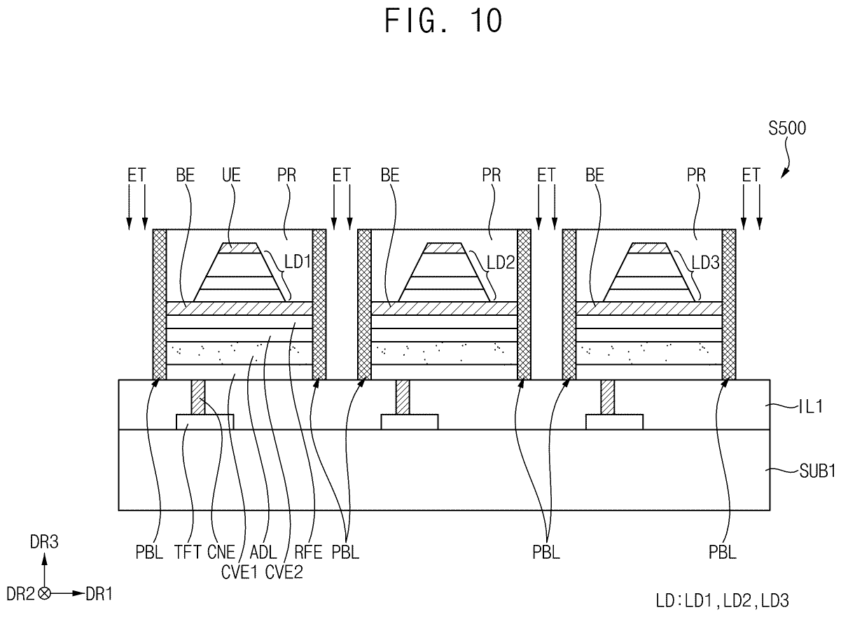

In one or more embodiments, a side surface of the first cover electrode CVE1, a side surface of the adhesive layer ADL, a side surface of the second cover electrode CVE2, a side surface of the reflective electrode RFE, and a side surface of the lower electrode BE may be substantially aligned along the third direction DR3. The first cover electrode CVE1, the adhesive layer ADL, the second cover electrode CVE2, the reflective electrode RFE, and the lower electrode BE may be patterned through the same etching process. A detailed description thereof will be described below with reference to FIG. 10.

The barrier layer PBL may entirely cover the side surface of the lower electrode BE. In one or more embodiments, as illustrated in FIG. 2, the barrier layer PBL may entirely cover the side surface of the first cover electrode CVE1, the side surface of the adhesive layer ADL, the side surface of the second cover electrode CVE2, the side surface of the reflective electrode RFE, and the side surface of the lower electrode BE.

The barrier layer PBL may protect the side surface of each of the first cover electrode CVE1, the adhesive layer ADL, the second cover electrode CVE2, the reflective electrode RFE, and the lower electrode BE during the manufacturing process of the display device DD. For example, the barrier layer PBL may protect the first cover electrode CVE1, the adhesive layer ADL, the second cover electrode CVE2, the reflective electrode RFE, and the lower electrode BE from a chlorine anion and a chlorine radical generated in the etching process. A detailed description thereof will be described below with reference to FIG. 10.

The barrier layer PBL may include an organic polymer material. In one or more embodiments, the barrier layer PBL may include a fluorine-based polymer. The fluorine-based polymer may include a fluorocarbon (CₓF_{y}) group or a fluorohydrocarbon (CₓH_{y}F_{z}) group. For example, the fluorine-based polymer may include —CF₂— group, —CHF— group, etc. These may be used alone or in combination with each other.

The first to third light-emitting elements LD1, LD2, LD3 may be located on the lower electrode BE. The first light-emitting element LD1 may generate light of a first color, the second light-emitting element LD2 may generate light of a second color, and the third light-emitting element LD3 may generate light of a third color. For example, the first color may be red, the second color may be green, and the third color may be blue. However, the present disclosure is not limited thereto.

In one or more embodiments, each of the first to third light-emitting elements LD1, LD2, and LD3 may be a micro light-emitting diode. Each of the first to third light-emitting elements LD1, LD2, and LD3 may include the first semiconductor layer PSL, the active layer MQW, and the second semiconductor layer NSL.

The first semiconductor layer PSL may be located on the lower electrode BE. The first semiconductor layer PSL may include a p-type semiconductor. For example, the first semiconductor layer PSL may include p-type doped AlGaInN, GaN, AlGaN, InGaN, AlN, InN, etc. These may be used alone or in combination with each other. The first semiconductor layer PSL may be doped with a p-type dopant. The p-type dopant may include magnesium (Mg), zinc (Zn), calcium (Ca), selenium (Se), barium (Ba), etc. For example, the first semiconductor layer PSL may include p-GaN doped with p-type Mg.

For example, the first semiconductor layer PSL may have a tapered shape. In other words, a width of an upper surface of the first semiconductor layer PSL may be less than a width of a lower surface of the first semiconductor layer PSL. In this specification, the width may refer to a length in the first direction DR1. However, the shape of the first semiconductor layer PSL is not limited thereto.

The active layer MQW may be located on the first semiconductor layer PSL. The active layer MQW may generate light by combination of electron-hole pairs according to an electric signal applied through the first semiconductor layer PSL and the second semiconductor layer NSL.

The active layer MQW may include a material having a single or multiple quantum well structure. For example, when the active layer MQW includes a material having a multiple quantum well structure, the active layer MQW may have a structure in which a plurality of well layers and barrier layers are alternately stacked. The well layers may include InGaN, and the barrier layers may include GaN or AlGaN. However, the present disclosure is not limited thereto.

The active layer MQW may include different Group III to Group V semiconductor materials depending on the wavelength of the emitted light. For example, when the semiconductor materials included in the active layer MQW include indium (In), the color of the light emitted may vary depending on the content of indium (In). When the content of indium (In) decreases, the wavelength band of the emitted light may shift to a red wavelength band, and when the content of indium (In) increases, the wavelength band of the emitted light may shift to a blue wavelength band.

For example, the active layer MQW may have a tapered shape. In other words, a width of an upper surface of the active layer MQW may be less than a width of a lower surface of the active layer MQW. However, the shape of the active layer MQW is not limited to this.

The second semiconductor layer NSL may be located on the active layer MQW. The second semiconductor layer NSL may include an n-type semiconductor. For example, the second semiconductor layer NSL may include n-type doped AlGaInN, GaN, AlGaN, InGaN, AlN, InN, etc. These may be used alone or in combination with each other. The second semiconductor layer NSL may be doped with an n-type dopant. The n-type dopant may include silicon (Si), germanium (Ge), tin (Sn), etc. For example, the second semiconductor layer NSL may include n-GaN doped with n-type Si.

For example, the second semiconductor layer NSL may have a tapered shape. In other words, a width of an upper surface of the second semiconductor layer NSL may be less than a width of a lower surface of the second semiconductor layer NSL. However, the shape of the second semiconductor layer NSL is not limited to this.

In one or more embodiments, each of the first to third light-emitting elements LD1, LD2, and LD3 may have a mesa structure. That is, a side surface of the first semiconductor layer PSL may protrude further in a direction away from a center of the second semiconductor layer NSL than a side surface of the second semiconductor layer NSL. In addition, the side surface of the first semiconductor layer PSL may protrude further in a direction away from a center of the active layer MQW than a side surface of the active layer MQW. For example, each of the first to third light-emitting elements LD1, LD2, and LD3 may have a tapered structure. However, the present disclosure is not limited thereto, and each of the first to third light-emitting elements LD1, LD2, and LD3 may have a square cross-sectional shape.

The upper electrode UE may be located on the second semiconductor layer NSL. The upper electrode UE may be electrically connected with the upper electrode connection line UCL. Accordingly, the upper electrode UE may be provided with a common voltage through the upper electrode connection line UCL. In addition, the upper electrode UE may be electrically connected with the second semiconductor layer NSL. For example, the upper electrode UE may be referred to as an n-type electrode. The upper electrode UE may include a metal, an alloy, a metal nitride, a conductive metal oxide, a transparent conductive material, etc. In one or more embodiments, the upper electrode UE may include a transparent conductive oxide. In this case, the upper electrode UE may include indium tin oxide (“ITO”). However, the present disclosure is not limited thereto. For example, the upper electrode UE may serve as a cathode electrode.

For example, the upper electrode UE may have a tapered shape. In other words, a width of an upper surface of the upper electrode UE may be less than a width of a lower surface of the upper electrode UE. However, the shape of the upper electrode UE is not limited to this.

For example, the lower surface of the upper electrode UE may entirely overlap the upper surface of the corresponding second semiconductor layer NSL. However, the present disclosure is not limited thereto.

The element protection layer LPV may entirely cover the side surface of the light-emitting element LD and the side surface of the upper electrode UE. That is, the element protection layer LPV may entirely cover the side surface of each of the first light-emitting element LD1, the second light-emitting element LD2, the third light-emitting element LD3, and the upper electrode UE. Accordingly, the light-emitting element LD may not directly contact the upper electrode connection line UCL. The element protection layer LPV may include an inorganic insulating material. Examples of the inorganic insulating material that may be used as the element protection layer LPV may include silicon oxide (SiOₓ), silicon nitride (SiNx), silicon oxynitride (SiOxNy), etc. These may be used alone or in combination with each other. The element protection layer LPV may define a second opening exposing a portion of the upper electrode UE.

The second insulating layer IL2 may be located on the first insulating layer IL1. The second insulating layer IL2 may cover the barrier layer PBL, the light-emitting element LD, and the element protection layer LPV. The second insulating layer IL2 may flatten a step difference caused by the light-emitting element LD. The second insulating layer IL2 may include an inorganic insulating material or an organic insulating material. The second insulating layer IL2 may define the second opening exposing the portion of the upper electrode UE together with the element protection layer LPV. That is, the second opening may penetrate the element protection layer LPV and the second insulating layer IL2 in the thickness direction.

The upper electrode connection line UCL may be located on the upper electrode UE. The upper electrode connection line UCL may be connected to the upper electrode UE through the second opening penetrating the second insulating layer IL2 and the element protection layer LPV. For example, the upper electrode connection line UCL may be connected with the upper electrode UE located on an upper surface of the first light-emitting element LD1, with the upper electrode UE located on an upper surface of the second light-emitting element LD2, and with the upper electrode UE located on an upper surface of the third light-emitting element LD3. In one or more embodiments, the upper electrode connection line UCL may be connected with a common voltage line that provides the common voltage. Accordingly, the upper electrode connection line UCL may transmit the common voltage to the upper electrode UE.

The upper protection layer PPV may be located on the upper electrode connection line UCL. The upper protection layer PPV may cover the upper electrode UE and the upper electrode connection line UCL. The upper protection layer PPV may include an inorganic insulating material or an organic insulating material.

FIG. 3 is a cross-sectional view illustrating a display device according to one or more other embodiments of the present disclosure.

Referring to FIG. 3, a display device DD2 according to one or more other embodiments of the present disclosure may include the first substrate SUB1, the driving element TFT, the connection electrode CNE, the first insulating layer IL1, the first cover electrode CVE1, the adhesive layer ADL, the second cover electrode CVE2, a reflective electrode RFE, a lower electrode BE, a barrier layer PBL′, the light-emitting element LD, the upper electrode UE, the element protection layer LPV, the second insulating layer IL2, the upper electrode connection line UCL, and the upper protection layer PPV.

The display device DD2 may be substantially the same as the display device DD described above with reference to FIGS. 1 and 2, except that the barrier layer PBL′ entirely covers only a side surface of the lower electrode BE and a side surface of the reflective electrode RFE. In other words, the display device DD2 may be substantially the same as the display device DD described above with reference to FIGS. 1 and 2, except that the barrier layer PBL′ does not cover a side surface of the first cover electrode CVE1, a side surface of the adhesive layer ADL, or a side surface of the second cover electrode CVE2. Hereinafter, redundant descriptions of the display device DD described above with reference to FIGS. 1 and 2 may be omitted or may be summarized.

The side surface of the first cover electrode CVE1, the side surface of the adhesive layer ADL, and the side surface of the second cover electrode CVE2 may protrude further in a direction away from a center of the lower electrode BE than the side surface of the reflective electrode RFE and the side surface of the lower electrode BE. The first cover electrode CVE1, the adhesive layer ADL, and the second cover electrode CVE2 may be patterned through an etching process that is different from an etching process for patterning the reflective electrode RFE and the lower electrode BE.

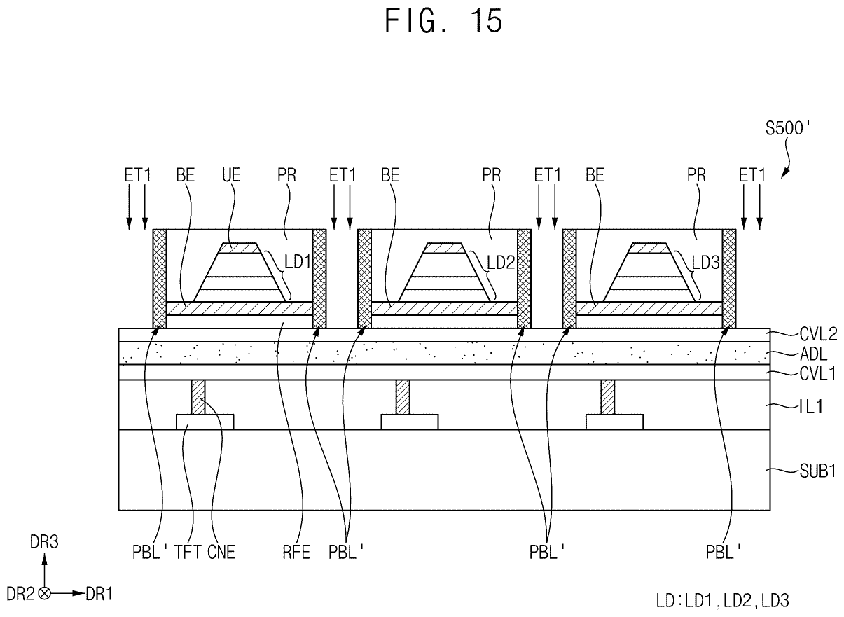

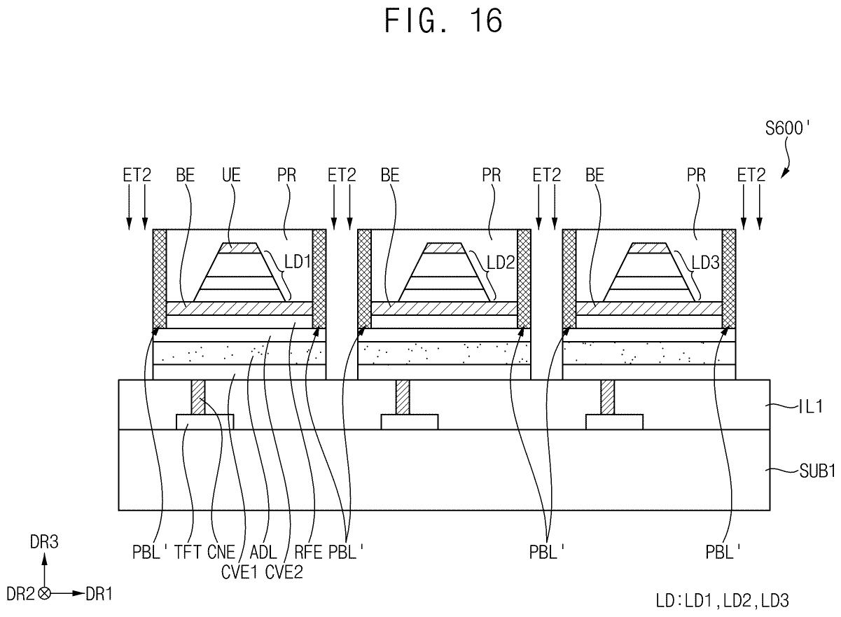

For example, the reflective electrode RFE and the lower electrode BE may be patterned through a first etching process, and the first cover electrode CVE1, the adhesive layer ADL, and the second cover electrode CVE2 may be patterned through a second etching process that is different from the first etching process. The side surface of the reflective electrode RFE and the side surface of the lower electrode BE may be substantially aligned along the third direction DR3. The side surface of the first cover electrode CVE1, the side surface of the adhesive layer ADL, and the side surface of the second cover electrode CVE2 may be substantially aligned along the third direction DR3. A detailed description thereof will be described below with reference to FIGS. 15 and 16.

The barrier layer PBL′ may entirely cover the side surface of the lower electrode BE. In one or more embodiments, as illustrated in FIG. 3, the barrier layer PBL′ may entirely cover only the side surface of the reflective electrode RFE and the side surface of the lower electrode BE. In other words, the barrier layer PBL′ may not cover the side surface of the first cover electrode CVE1, the side surface of the adhesive layer ADL, and the side surface of the second cover electrode CVE2.

The barrier layer PBL′ may protect the side surface of the reflective electrode RFE and the side surface of the lower electrode BE during the manufacturing process of the display device DD2. For example, the barrier layer PBL′ may protect the reflective electrode RFE and the lower electrode BE from a chlorine anion and a chlorine radical generated in the etching process. A detailed description thereof will be described below with reference to FIG. 15.

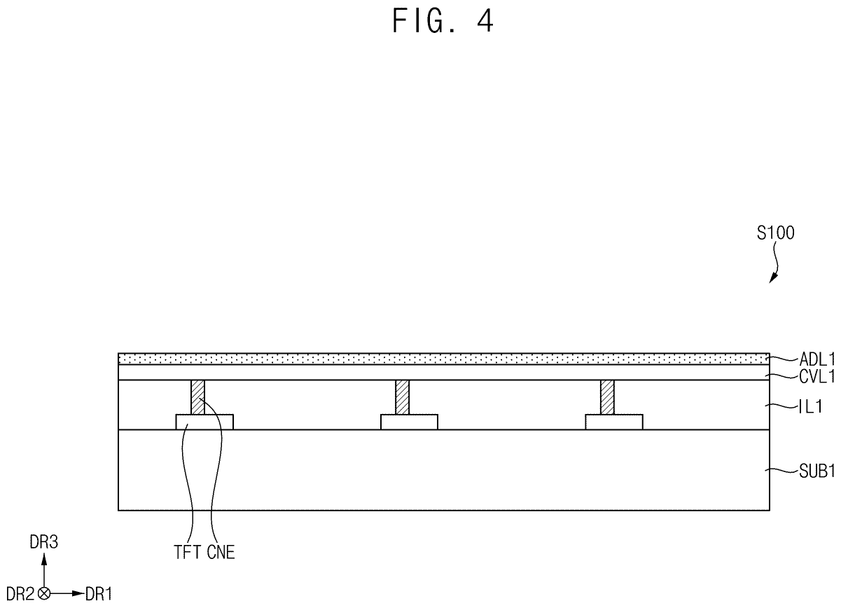

FIGS. 4, 5, 6, 7, 8, 9, 10, 11, 12, and 13 are cross-sectional views illustrating a method of manufacturing a display device according to one or more embodiments of the present disclosure. The method of manufacturing the display device described below with reference to FIGS. 4 to 13 may be a method of manufacturing the display device DD described above with reference to FIG. 2. Hereinafter, redundant descriptions of the display device DD described above with reference to FIG. 2 may be omitted or may be summarized.

Referring to FIGS. 4 and 5, the driving element TFT may be formed on the first substrate SUB1, and a preliminary element layer PLD and a first preliminary electrode layer PBE may be formed on a second substrate SUB2 (S100) (an used herein, “formed on” or “located on” may mean “above”).

As illustrated in FIG. 4, the driving element TFT may be formed on the first substrate SUB1. In one or more embodiments, the first substrate SUB1 may be a silicon wafer. The first insulating layer IL1 may be formed on the first substrate SUB1. The first insulating layer IL1 may cover the driving element TFT. The first insulating layer IL1 may define the first opening exposing a portion of the driving element TFT. The connection electrode CNE may be formed on the driving element TFT. The connection electrode CNE may be connected to the driving element TFT through the first opening.

A first cover electrode layer CVL1 may be formed on the first insulating layer IL1. The first cover electrode layer CVL1 may cover the driving element TFT and the connection electrode CNE. The first cover electrode layer CVL1 may reduce or prevent penetration of impurities, moisture, etc. into the driving element TFT and the connection electrode CNE. In one or more embodiments, the first cover electrode layer CVL1 may include titanium (Ti), titanium nitride (TiN), etc. These may be used alone or in combination with each other.

A first adhesive layer ADL1 may be formed on the first cover electrode layer CVL1. In one or more embodiments, the first adhesive layer ADL1 may include gold (Au), tin (Sn), silver (Ag), aluminum (AI), titanium (Ti), etc.

As illustrated in FIG. 5, the preliminary element layer PLD may be formed on the second substrate SUB2. For example, the second substrate SUB2 may include gallium nitride (GaN), sapphire, silicon (Si), silicon carbide (SiC), gallium arsenide (GaAs), or zinc oxide (ZnO). In one or more embodiments, the second substrate SUB2 may be a silicon wafer.

The preliminary element layer PLD may include the second semiconductor layer NSL, the active layer MQW, and the first semiconductor layer PSL sequentially stacked along the third direction DR3. For example, each of the first semiconductor layer PSL, the active layer MQW, and the second semiconductor layer NSL may be formed of a GaN-based semiconductor. In this case, the first semiconductor layer PSL may include p-GaN doped with p-type Mg, and the second semiconductor layer NSL may include n-GaN doped with n-type Si. The active layer MQW may have a structure in which a plurality of well layers and barrier layers are alternately stacked. The well layers may include InGaN, and the barrier layers may include GaN or AlGaN.

The first preliminary electrode layer PBE may be formed on the preliminary element layer PLD. In one or more embodiments, the first preliminary electrode layer PBE may include a transparent conductive oxide. In this case, the first preliminary electrode layer PBE may include indium tin oxide (“ITO”).

A reflective electrode layer RFL may be formed on the first preliminary electrode layer PBE. The reflective electrode layer RFL may include a metal having high light reflectivity. In one or more embodiments, the reflective electrode layer RFL may include aluminum (Al) or silver (Ag).

A second cover electrode layer CVL2 may be formed on the reflective electrode layer RFL. The second cover electrode layer CVL2 may reduce or prevent penetration of impurities, moisture, etc. into the reflective electrode layer RFL and the first preliminary electrode layer PBE. In one or more embodiments, the second cover electrode layer CVL2 may include titanium (Ti), titanium nitride (TiN), etc. These may be used alone or in combination with each other.

A second adhesive layer ADL2 may be formed on the second cover electrode layer CVL2. In one or more embodiments, the second adhesive layer ADL2 may include gold (Au), tin (Sn), silver (Ag), aluminum (AI), titanium (Ti), etc.

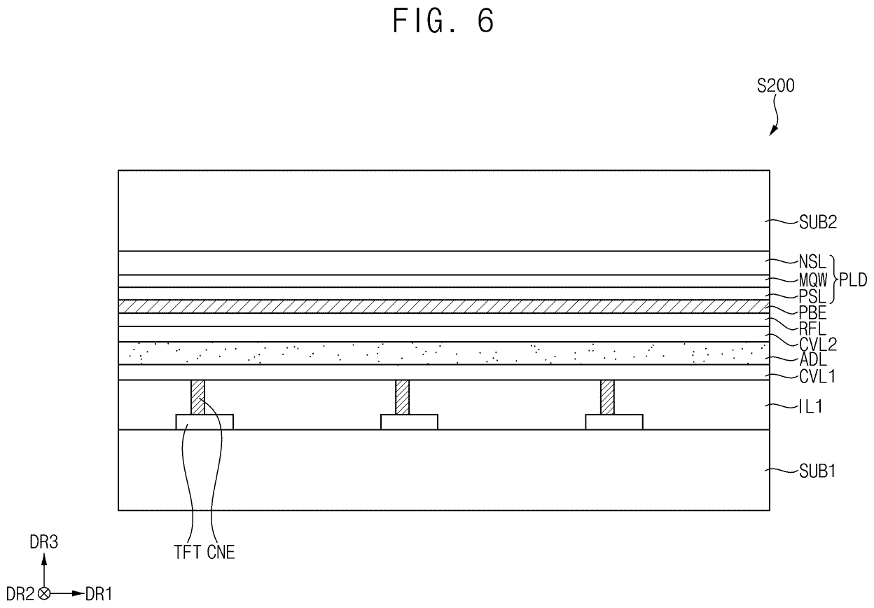

Referring to FIG. 6, the first preliminary electrode layer PBE may be located on the driving element TFT. For example, the first substrate SUB1 and the second substrate SUB2 may be bonded so that the first preliminary electrode layer PBE is positioned on the driving element TFT (S200). In this case, the first substrate SUB1 and the second substrate SUB2 may be bonded so that the first adhesive layer ADL1 and the second adhesive layer ADL2 are facing each other. In other words, the second substrate SUB2 may be bonded to the first substrate SUB1 with the second substrate SUB2 illustrated in FIG. 6 turned over, as compared to the substrate SUB2 illustrated in FIG. 5.

The first adhesive layer ADL1 and the second adhesive layer ADL2 may contact each other to form the adhesive layer ADL. In one or more embodiments, the adhesive layer ADL may include a tin-gold (Sn—Au) alloy. The adhesive layer ADL may attach the first cover electrode layer CVL1 and the second cover electrode layer CVL2.

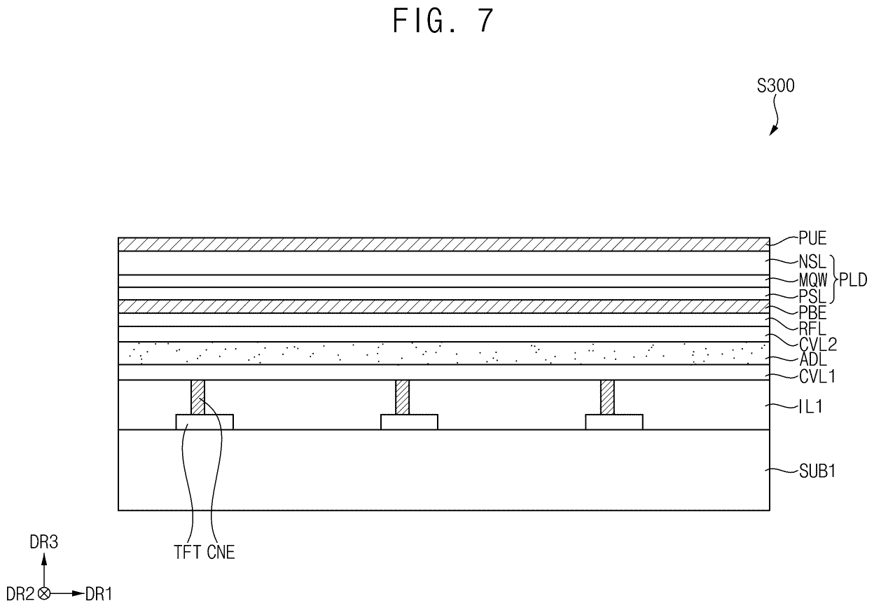

Referring to FIG. 7, the second substrate SUB2 may be removed, and a second preliminary electrode layer PUE may be formed on the preliminary element layer PLD (S300). For example, the second substrate SUB2 may be removed by a laser lift off process. However, the present disclosure is not limited thereto.

In one or more embodiments, after removing the second substrate SUB2, and before forming the second preliminary electrode layer PUE, a thickness of the preliminary element layer PLD may be adjusted. For example, the thickness of the preliminary element layer PLD may be reduced through an etching process.

The second preliminary electrode layer PUE may be formed on the preliminary element layer PLD. In one or more embodiments, the second preliminary electrode layer PUE may include a transparent conductive oxide. In this case, the second preliminary electrode layer PUE may include indium tin oxide (“ITO”).

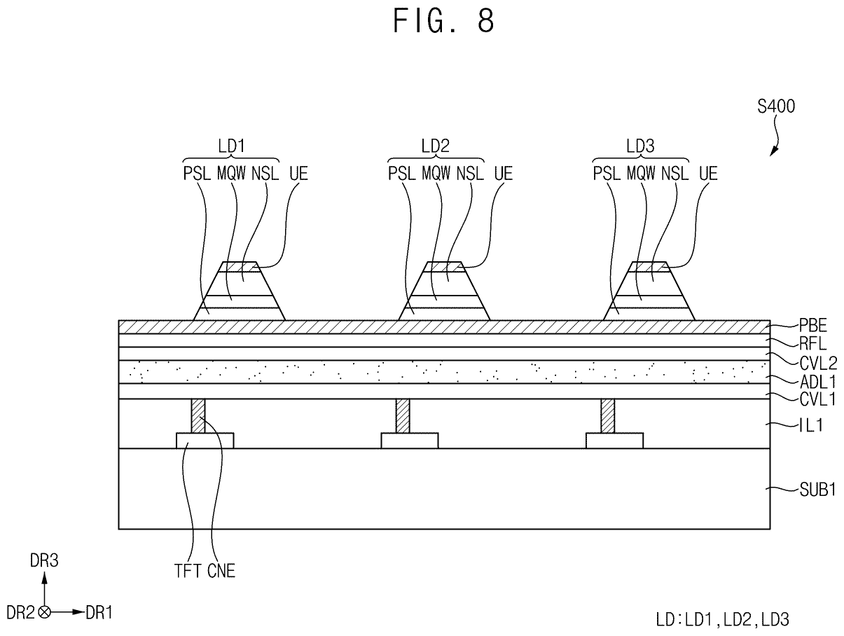

Referring to FIG. 8, the light-emitting element LD and the upper electrode UE on the light-emitting element LD may be formed by patterning the preliminary element layer PLD and the second preliminary electrode layer PUE, respectively (S400). In one or more embodiments, the preliminary element layer PLD and the second preliminary electrode layer PUE may be patterned concurrently or substantially simultaneously.

The light-emitting element LD may include the first light-emitting element LD1, the second light-emitting element LD2, and the third light-emitting element LD3. For example, each of the first light-emitting element LD1, the second light-emitting element LD2, the third light-emitting element LD3, and the upper electrode UE may have a tapered shape.

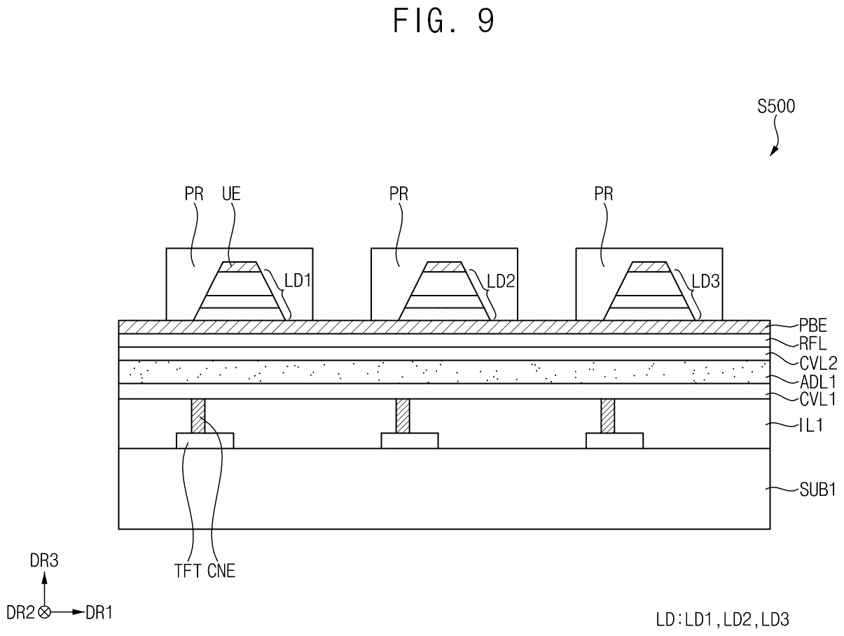

Referring to FIGS. 9, 10, and 11, the lower electrode BE, and the barrier layer PBL that entirely covers a side surface of the lower electrode BE, may be concurrently or substantially simultaneously formed under the light-emitting element LD by patterning the first preliminary electrode layer PBE (S500).

As illustrated in FIG. 9, a plurality of photoresist patterns PR may be formed on the first preliminary electrode layer PBE. The photoresist patterns PR may be spaced apart from each other in the first direction DR1. The photoresist patterns PR may respectively cover the upper electrodes UE and light-emitting elements LD.

As illustrated in FIG. 10, the lower electrode BE may be formed by patterning the first preliminary electrode layer PBE using the photoresist pattern PR as an etching mask through an etching process ET. That is, a portion of the first preliminary electrode layer PBE that overlaps the photoresist patterns PR in a plan view may remain, and a portion of the first preliminary electrode layer PBE that does not overlap the photoresist patterns PR in a plan view may be removed.

The first preliminary electrode layer PBE may be patterned through a dry etching process using an etching gas. The etching gas may include a chlorine-based gas such as BCl₃, BCl₃/Cl₂, BCl₃/Cl₂/Ar, etc.

In one or more embodiments, the etching gas may further include a fluorine-based gas. That is, the first preliminary electrode layer PBE may be patterned through a dry etching process using the etching gas including a fluorine-based gas. For example, the fluorine-based gas may include CF₄, C₃F₆, C₄F₈, CHF₃, CH₂F₂, C₂HF₅, etc. These may be used alone or in combination with each other.

As the etching gas further includes the fluorine-based gas, the barrier layer PBL that entirely covers the side surface of the lower electrode BE may be formed concurrently or substantially simultaneously with the forming of the lower electrode BE. For example, when dry etching the first preliminary electrode layer PBE by supplying the etching gas including the fluorine-based gas, and adjusting a process condition, at the same time that the etching gas etches the first preliminary electrode layer PBE in a thickness direction along the photoresist patterns PR, the fluorine-based gas may form the barrier layer PBL. Accordingly, the barrier layer PBL may entirely cover a side surface of each of the photoresist patterns PR and the side surface of the lower electrode BE. In other words, the barrier layer PBL may be formed concurrently or substantially simultaneously in the process of forming the lower electrode BE without an additional process for forming the barrier layer PBL.

In one or more embodiments, the barrier layer PBL may include a fluorine-based polymer. The fluorine-based polymer may include a fluorocarbon (CₓF_{y}) group or a fluorohydrocarbon (CₓH_{y}F_{z}) group. For example, the fluorine-based polymer may include —CF₂— group, —CHF— group, etc.

In one or more embodiments, the first cover electrode layer CVL1, the adhesive layer ADL, the second cover electrode layer CVL2, and the reflective electrode layer RFL may be patterned concurrently or substantially simultaneously with the first preliminary electrode layer PBE through the etching process ET. That is, the first cover electrode layer CVL1 may be patterned to form the first cover electrode CVE1, the second cover electrode layer CVL2 may be patterned to form the second cover electrode CVE2, and the reflective electrode layer RFL may be patterned to form the reflective electrode RFE. Accordingly, the barrier layer PBL may entirely cover a side surface of the first cover electrode CVE1, a side surface of the patterned adhesive layer ADL and a side surface of the second cover electrode CVE2, a side surface of the reflective electrode RFE, and the side surface of the lower electrode BE. However, the present disclosure is not limited thereto.

When the etching gas includes a chlorine-based gas, a chlorine anion or a chlorine radical generated in the etching process ET may remain on a surface of an electrode, causing corrosion of the electrode.

To reduce or prevent the corrosion problem, the display device DD according to one or more embodiments of the present disclosure may include the barrier layer PBL that entirely covers the side surface of each of the first cover electrode CVE1, the adhesive layer ADL, the second cover electrode CVE2, the reflective electrode RFE, and the lower electrode BE. The barrier layer PBL may protect the first cover electrode CVE1, the adhesive layer ADL, the second cover electrode CVE2, the reflective electrode RFE, and the lower electrode BE from a chlorine anion and a chlorine radical generated in the etching process ET. Accordingly, corrosion of the first cover electrode CVE1, the adhesive layer ADL, the second cover electrode CVE2, the reflective electrode RFE, and the lower electrode BE may be reduced or prevented, and the reliability of light-emitting element LD may be improved.

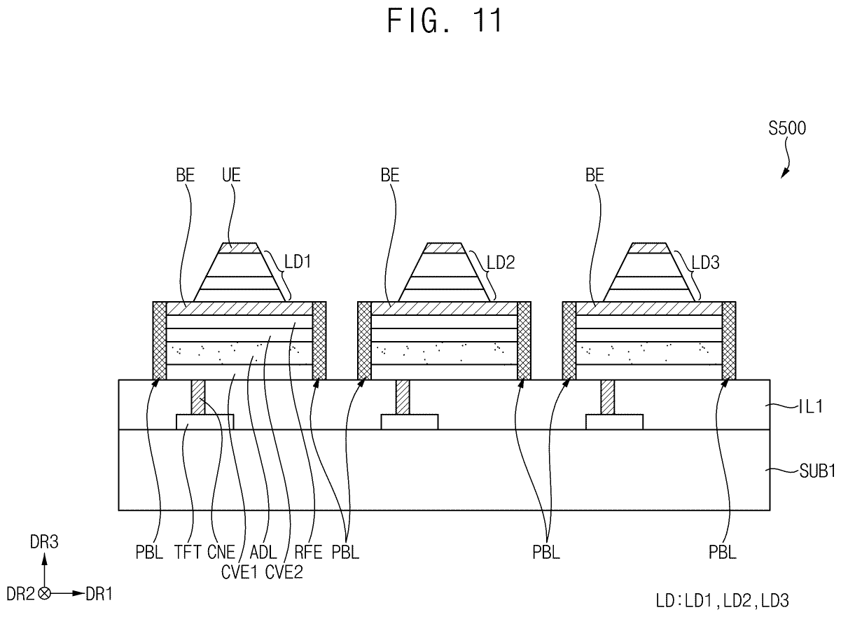

As illustrated in FIG. 11, the photoresist patterns PR remaining on the lower electrode BE may be removed. In this case, the barrier layer PBL formed on the side surface of each of the photoresist patterns PR may be removed together with the photoresist patterns PR.

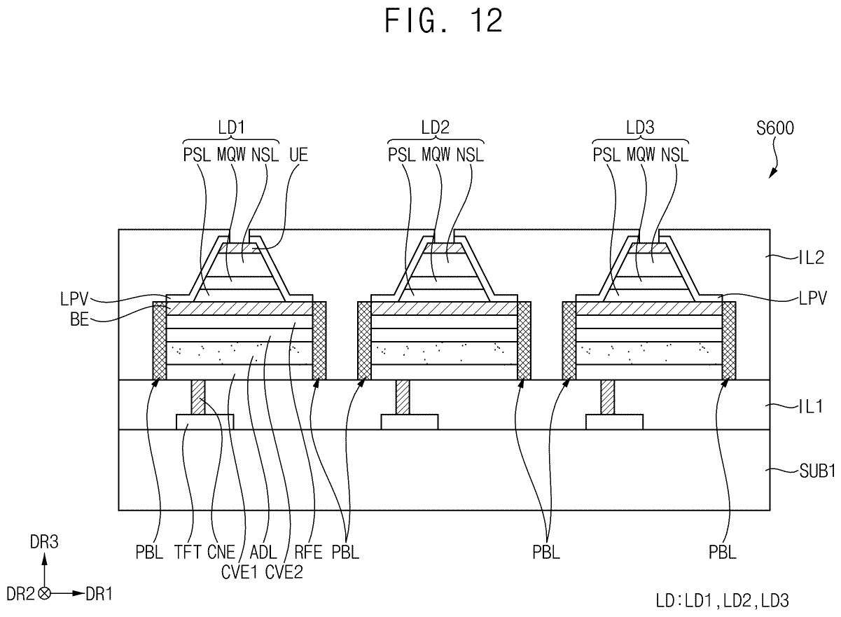

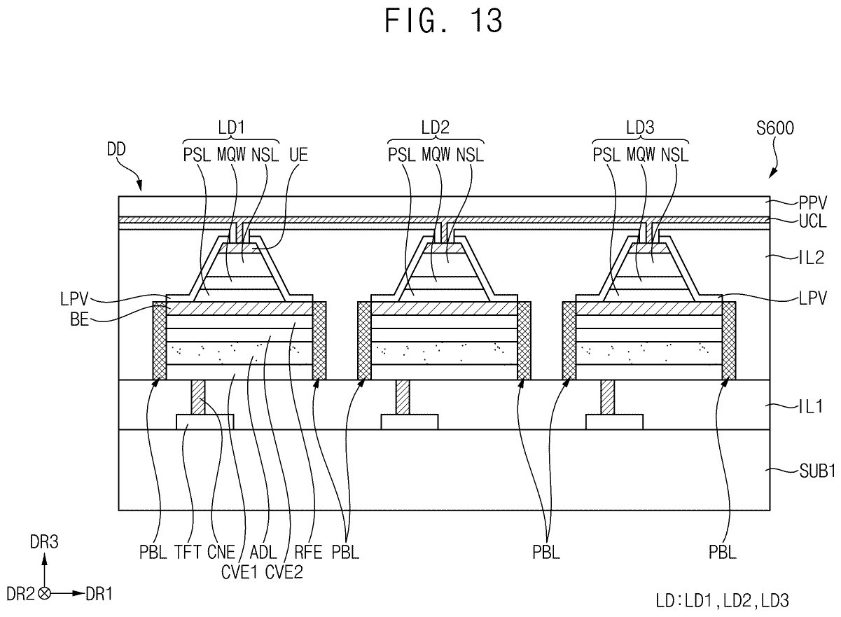

Referring to FIGS. 12 and 13, the element protection layer LPV that entirely covers a side surface of the light-emitting element LD and a side surface of the upper electrode UE may be formed, and the upper protection layer PPV may be formed on the element protection layer LPV (S600).

As illustrated in FIG. 12, the element protection layer LPV may entirely cover a side surface of each of the first light-emitting element LD1, the second light-emitting element LD2, the third light-emitting element LD3, and the upper electrode UE. The element protection layer LPV may expose a portion of the upper electrode UE. The element protection layer LPV may include an inorganic insulating material.

In one or more embodiments, the element protection layer LPV may be formed after forming the barrier layer PBL. For example, the element protection layer LPV may be formed after the barrier layer PBL is formed and the photoresist patterns PR are removed. However, the present disclosure is not limited thereto.

In one or more embodiments, the element protection layer LPV may be formed before forming the barrier layer PBL. For example, the element protection layer LPV may be formed after the forming the light-emitting element LD and the upper electrode UE (S400). After forming the element protection layer LPV, the photoresist patterns PR for patterning the first preliminary electrode layer PBE may be formed. In this case, each of the photoresist patterns PR may cover the upper electrode UE, the corresponding light-emitting element LD, and the element protection layer LPV.

The second insulating layer IL2 may be formed on the first insulating layer IL1. The second insulating layer IL2 may cover the barrier layer PBL, the light-emitting element LD, and the element protection layer LPV. The second insulating layer IL2 may flatten a step difference caused by the light-emitting element LD. The second insulating layer IL2 may include an inorganic insulating material or an organic insulating material. The second insulating layer IL2 may define the second opening exposing the portion of the upper electrode UE together with the element protection layer LPV.

As illustrated in FIG. 13, the upper electrode connection line UCL may be formed on the upper electrode UE. The upper electrode connection line UCL may be connected to the upper electrode UE through the second opening.

The upper protection layer PPV may be formed on the upper electrode connection line UCL. The upper protection layer PPV may cover the upper electrode UE and the upper electrode connection line UCL. The upper protection layer PPV may include an inorganic insulating material or an organic insulating material.

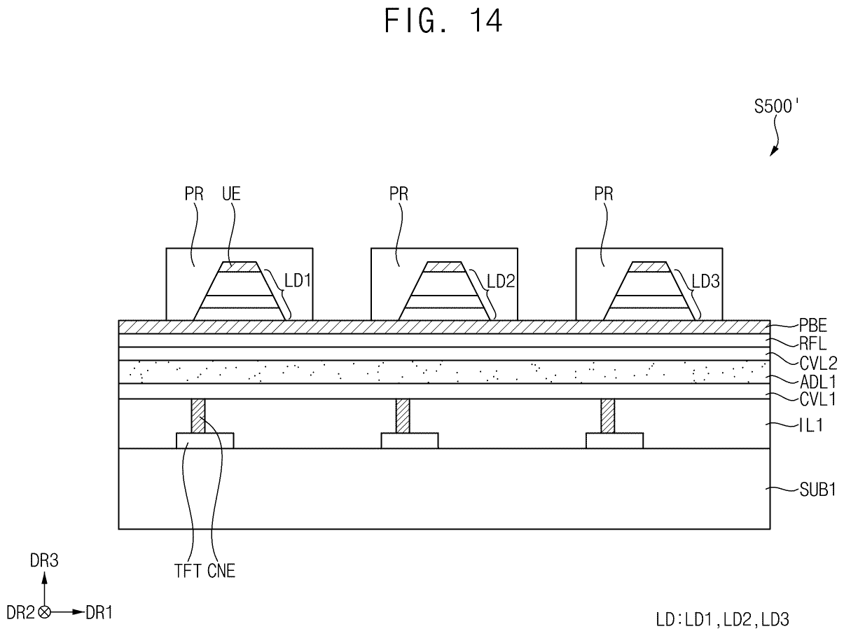

FIGS. 14, 15, 16, 17, and 18 are cross-sectional views illustrating a method of manufacturing a display device according to one or more other embodiments of the present disclosure. The method of manufacturing the display device described below with reference to FIGS. 14 to 18 may be a method of manufacturing the display device DD2 described above with reference to FIG. 3. Hereinafter, redundant descriptions of the display device DD2 described above with reference to FIG. 3 may be omitted or may be summarized.

The method of manufacturing the display device described below with reference to FIGS. 14 to 18 may include forming the driving element TFT on the first substrate SUB1 and forming the preliminary element layer PLD and the first preliminary electrode layer PBE on the second substrate SUB2 (S100) described above with reference to FIGS. 4 and 5. In addition, the method of manufacturing the display device may further include bonding the first substrate SUB1 and the second substrate SUB2 (S200) described above with reference to FIG. 6. In addition, the method of manufacturing the display device may further include removing the second substrate SUB2 and forming the second preliminary electrode layer PUE (S300) described above with reference to FIG. 7. In addition, the method of manufacturing the display device may further include patterning the preliminary element layer PLD and the second preliminary electrode layer PUE (S400) described above with reference to FIG. 8. Hereinafter, redundant descriptions of the method of manufacturing the display device described above with reference to FIGS. 4 to 13 may be omitted or may be summarized.

Referring to FIGS. 14 and 15, the lower electrode BE and the barrier layer PBL′ that entirely covers a side surface of the lower electrode BE may be concurrently or substantially simultaneously formed under the light-emitting element LD by patterning the first preliminary electrode layer PBE (S500′).

As illustrated in FIG. 14, a plurality of photoresist patterns PR may be formed on the first preliminary electrode layer PBE. The photoresist patterns PR may be spaced apart from each other in the first direction DR1. Each of the photoresist patterns PR may cover the upper electrode UE and a corresponding one light-emitting element LD.

As illustrated in FIG. 15, the lower electrode BE may be formed by patterning the first preliminary electrode layer PBE using the photoresist pattern PR as an etching mask through a first etching process ET1.

The first preliminary electrode layer PBE may be patterned through a dry etching process using an etching gas. The etching gas may include a chlorine-based gas such as BCl₃, BCl₃/Cl₂, BCl₃/Cl₂/Ar, etc.

In one or more embodiments, in the first etching process ET1, the etching gas may further include a fluorine-based gas. That is, the first preliminary electrode layer PBE may be patterned through a dry etching process using the etching gas including a fluorine-based gas. For example, the fluorine-based gas may include CF₄, C₃F₆, C₄F₈, CHF₃, CH₂F₂, C₂HF₅, etc. These may be used alone or in combination with each other.

As the etching gas further includes the fluorine-based gas, the barrier layer PBL′ that entirely covers the side surface of the lower electrode BE may be formed concurrently or substantially simultaneously with the lower electrode BE. For example, when dry etching the first preliminary electrode layer PBE by supplying the etching gas including the fluorine-based gas, and adjusting a process condition, at the same time that the etching gas etches the first preliminary electrode layer PBE in a thickness direction along the photoresist patterns PR, the fluorine-based gas may form the barrier layer PBL′. Accordingly, the barrier layer PBL′ may entirely cover a side surface of each of the photoresist patterns PR and the side surface of the lower electrode BE.

In one or more embodiments, the barrier layer PBL′ may include a fluorine-based polymer. The fluorine-based polymer may include a fluorocarbon (CₓF_{y}) group or a fluorohydrocarbon (CₓH_{y}F_{z}) group. For example, the fluorine-based polymer may include —CF₂— group, —CHF— group, etc.

In one or more embodiments, the reflective electrode layer RFL may be patterned concurrently or substantially simultaneously with the first preliminary electrode layer PBE through the first etching process ET1. That is, the reflective electrode RFE may be formed by patterning the reflective electrode layer RFL. Unlike the method of manufacturing the display device according to one or more embodiments of the present disclosure described above with reference to FIG. 10, the first cover electrode layer CVL1, the adhesive layer ADL, and the second cover electrode layer CVL2 might not be patterned through the first etching process ET1.

Accordingly, the barrier layer PBL′ may entirely cover the side surface of the reflective electrode RFE and the side surface of the lower electrode BE. The barrier layer PBL′ may protect the reflective electrode RFE and the lower electrode BE from a chlorine anion and a chlorine radical generated in the first etching process ET1. Accordingly, corrosion of the reflective electrode RFE and the lower electrode BE may be reduced or prevented, and the reliability of the light-emitting element LD may be improved.

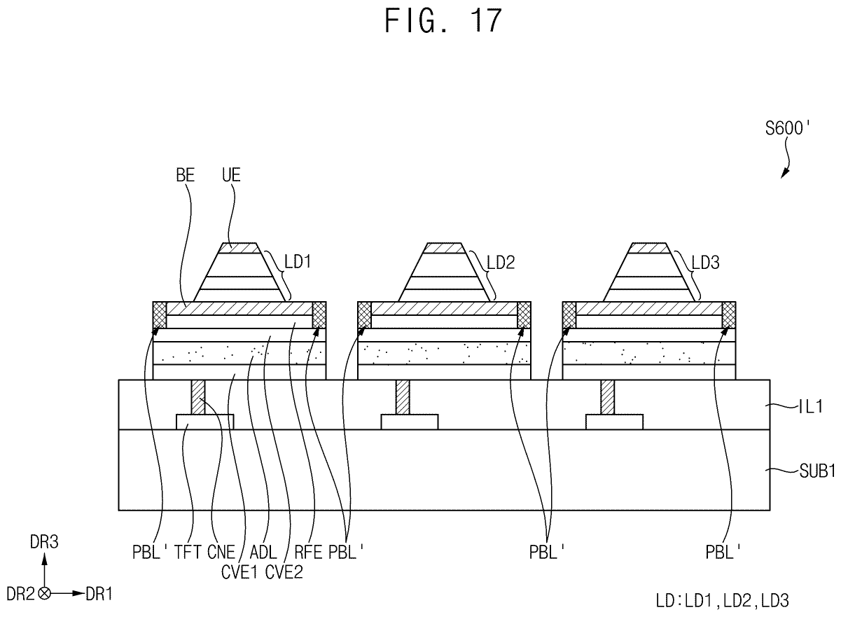

Referring to FIGS. 16 and 17, the first cover electrode layer CVL1, the adhesive layer ADL, and the second cover electrode layer CVL2 may be patterned through a second etching process ET2 (S600′). For example, the first cover electrode layer CVL1, the adhesive layer ADL, and the second cover electrode layer CVL2 may be patterned using the photoresist pattern PR and the barrier layer PBL′ as an etching mask through the second etching process ET2.

As illustrated in FIG. 16, the first cover electrode layer CVL1, the adhesive layer ADL, and the second cover electrode layer CVL2 may be patterned through a dry etching process using an etching gas. The etching gas may include a chlorine-based gas such as BCl₃, BCl₃/Cl₂, BCl₃/Cl₂/Ar, etc. In this case, in the second etching process ET2, the etching gas may not include a fluorine-based gas. The etching gas may etch the first cover electrode layer CVL1, the adhesive layer ADL, and the second cover electrode layer CVL2 in a thickness direction along the photoresist patterns PR and the barrier layer PBL′.

When the etching gas includes a chlorine-based gas, a chlorine anion and a chlorine radical may be generated in the second etching process ET2. The barrier layer PBL′ formed in the first etching process ET1 may protect the reflective electrode RFE and the lower electrode BE from a chlorine anion and a chlorine radical generated in the second etching process ET2. That is, the barrier layer PBL′ may protect the reflective electrode RFE and the lower electrode BE, which have a relatively important influence on the reliability of the light-emitting element LD. Accordingly, corrosion of the reflective electrode RFE and the lower electrode BE may be reduced or prevented, and the reliability of the light-emitting element LD may be improved.

As illustrated in FIG. 17, the photoresist patterns PR remaining on the lower electrode BE may be removed. In this case, the barrier layer PBL′ formed on the side surface of each of the photoresist patterns PR may be removed together with the photoresist patterns PR.

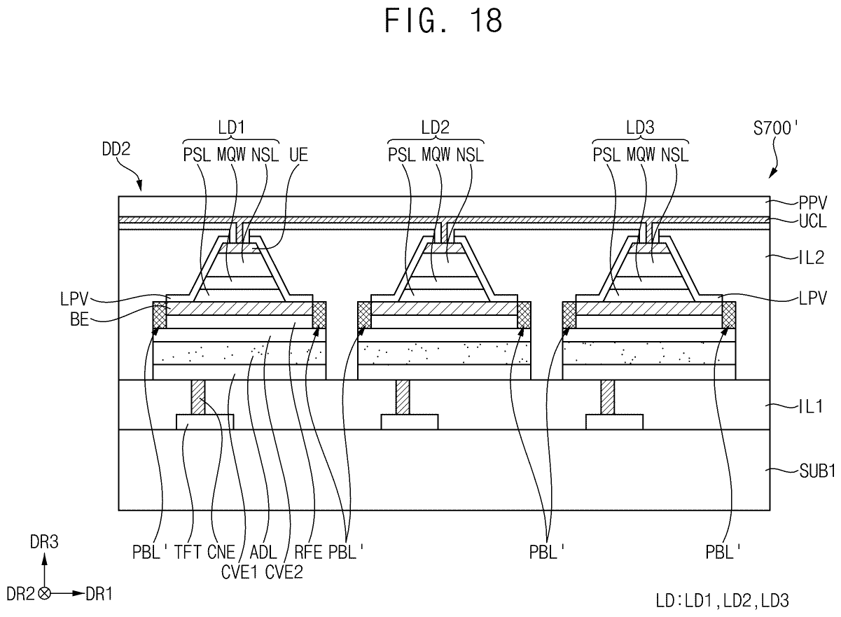

Referring to FIG. 18, the element protection layer LPV that entirely covers a side surface of the light-emitting element LD and a side surface of the upper electrode UE may be formed, and the upper protection layer PPV may be formed on the element protection layer LPV (S700′).

The element protection layer LPV may entirely cover the side surface of each of the first light-emitting element LD1, the second light-emitting element LD2, the third light-emitting element LD3, and the upper electrode UE. The element protection layer LPV may expose a portion of the upper electrode UE.

In one or more embodiments, the element protection layer LPV may be formed after forming the barrier layer PBL. In one or more embodiments, the element protection layer LPV may be formed before forming the barrier layer PBL″.

The second insulating layer IL2 may be formed on the first insulating layer IL1. The second insulating layer IL2 may cover the barrier layer PBL′, the light-emitting element LD, and the element protection layer LPV. The second insulating layer IL2 may flatten a step difference caused by the light-emitting element LD. The second insulating layer IL2 may define the second opening exposing the portion of the upper electrode UE together with the element protection layer LPV.

The upper electrode connection line UCL may be formed on the upper electrode UE. The upper electrode connection line UCL may be connected to the upper electrode UE through the second opening. The upper protection layer PPV may be formed on the upper electrode connection line UCL. The upper protection layer PPV may cover the upper electrode UE and the upper electrode connection line UCL.

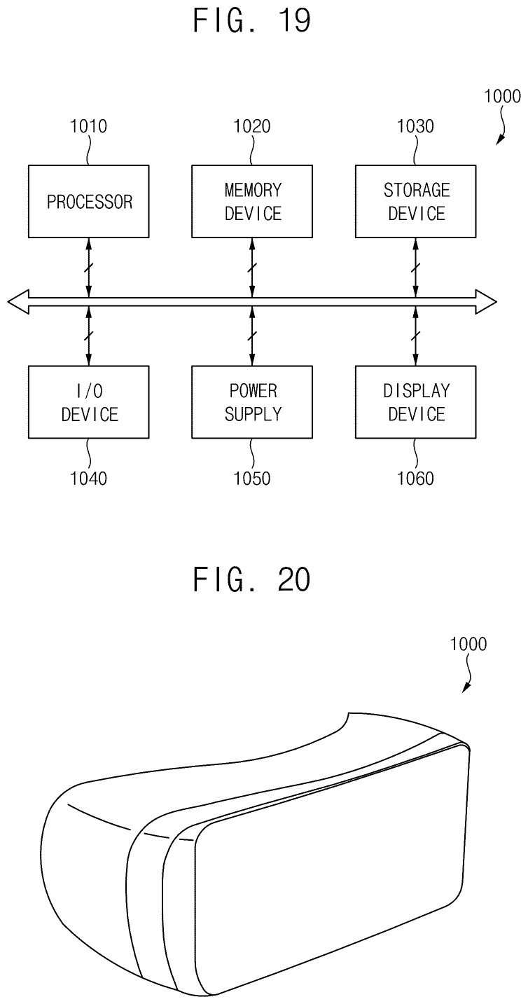

FIG. 19 is a block diagram illustrating an electronic device according to an embodiment of the present disclosure. FIG. 20 is a view illustrating an example in which the electronic device of FIG. 19 is implemented as a head mounted display device.

Referring to FIGS. 19 and 20, an electronic device 1000 may include a processor 1010, a memory device 1020, a storage device 1030, an input/output (I/O) device 1040, a power supply 1050, and a display device 1060. The display device 1060 may correspond to the display device DD of FIG. 2 or the display device DD2 of FIG. 3. In addition, the electronic device 1000 may further include a plurality of ports for communicating with a video card, a sound card, a memory card, a universal serial bus (USB) device, other systems, and the like.

In an embodiment, as illustrated in FIG. 20, the electronic device 1000 may be implemented as a head mounted display device. However, the electronic device 1000 is not limited thereto. For example, the electronic device 1000 may be implemented as a smart pad, a smart watch, a tablet PC, a smart phone, a car navigation system, a computer monitor, a laptop, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, with functional equivalents thereof to be included therein.

What is claimed is:

1. A display device comprising:
a substrate;
a driving element above the substrate;
a lower electrode above the driving element;
a barrier layer entirely covering a side surface of the lower electrode, and comprising a polymer; and
a light-emitting element above the lower electrode.

2. The display device of claim 1, wherein the barrier layer comprises a fluorine-based polymer.

3. The display device of claim 1, further comprising a reflective electrode between the driving element and the lower electrode, and having a side surface entirely covered by the barrier layer.

4. The display device of claim 3, wherein the reflective electrode comprises aluminum or silver.

5. The display device of claim 3, further comprising an adhesive layer between the driving element and the reflective electrode, comprising an alloy, and having a side surface entirely covered by the barrier layer.

6. The display device of claim 1, wherein the light-emitting element comprises:
a first semiconductor layer above the lower electrode;
an active layer above the first semiconductor layer; and
a second semiconductor layer above the active layer.

7. The display device of claim 1, further comprising:
an upper electrode above the light-emitting element; and
an element protection layer that entirely covers a side surface of the light-emitting element and a side surface of the upper electrode.

8. A method of manufacturing a display device, the method comprising:
forming a driving element above a first substrate;
forming a first preliminary electrode layer above the driving element;
forming a preliminary element layer above the first preliminary electrode layer;
forming a second preliminary electrode layer above the preliminary element layer;
forming a light-emitting element, and an upper electrode above the light-emitting element, by patterning the preliminary element layer and the second preliminary electrode layer, respectively; and
concurrently forming a lower electrode, and a barrier layer that entirely covers a side surface of the lower electrode, under the light-emitting element by patterning the first preliminary electrode layer.

9. The method of claim 8, wherein the barrier layer comprises a fluorine-based polymer.

10. The method of claim 8, wherein the patterning the first preliminary electrode layer comprises:
forming a photoresist pattern above the first preliminary electrode layer; and
using the photoresist pattern as a first etching mask through a first etching process.

11. The method of claim 10, wherein the patterning the first preliminary electrode layer comprises using an etching gas comprising a fluorine-based gas in a dry etching process.

12. The method of claim 11, wherein the fluorine-based gas comprises at least one of CF₄, C₃F₆, C₄F₈, CHF₃, CH₂F₂, or C₂HF₅.

13. The method of claim 10, further comprising:
forming an adhesive layer above the driving element; and
forming a reflective electrode layer above the adhesive layer and below the first preliminary electrode layer.

14. The method of claim 13, further comprising forming a reflective electrode by patterning the reflective electrode layer concurrently with the first preliminary electrode layer through the first etching process,
wherein the barrier layer entirely covers a side surface of the reflective electrode.

15. The method of claim 14, further comprising patterning the adhesive layer using the photoresist pattern and the barrier layer as a second etching mask through a second etching process after the patterning the first preliminary electrode layer.

16. The method of claim 13, wherein the adhesive layer and the reflective electrode layer are patterned concurrently with the first preliminary electrode layer through the first etching process, and
wherein the barrier layer is formed to entirely cover a side surface of the patterned adhesive layer and a side surface of the patterned reflective electrode layer.

17. The method of claim 10, further comprising:
removing the photoresist pattern after the forming the barrier layer; and
forming an element protection layer that entirely covers a side surface of the light-emitting element and a side surface of the upper electrode.

18. The method of claim 10, further comprising forming an element protection layer that entirely covers a side surface of the light-emitting element and a side surface of the upper electrode before the forming the barrier layer.

19. The method of claim 8, wherein the preliminary element layer and the second preliminary electrode layer are patterned concurrently.

20. The method of claim 8, wherein the forming the first preliminary electrode layer above the driving element comprises:
forming the first preliminary electrode layer above a second substrate;
bonding the first substrate and the second substrate so that the first preliminary electrode layer is above the driving element; and
removing the second substrate.

21. An electronic device comprising:
a display device comprising a light-emitting element; and
a power supply configured to provide power to the display device,
wherein the display device comprises:
a substrate;
a driving element above the substrate;
a lower electrode above the driving element;
a barrier layer entirely covering a side surface of the lower electrode, and comprising a polymer; and
the light-emitting element above the lower electrode.
